(19) United States
(12) Patent Application Publication
(10) Pub. No.: US 2026/0324261 A1
(43) Pub. Date: Oct. 15, 2026

(54) ELECTRONIC APPARATUS AND METHOD FOR MANUFACTURING THE ELECTRONIC APPARATUS

(71) Applicant: Samsung Display Co., Ltd., Yongin-si (KR)

(72) Inventors: Hongyeon LEE, Yongin-si (KR); Hyeoji KANG, Yongin-si (KR); Ohjeong KWON, Yongin-si (KR); Daewon KIM, Yongin-si (KR); Jeongsoo KIM, Yongin-si (KR); Taeho KIM, Yongin-si (KR); Seungyeon JEONG, Yongin-si (KR)

(73) Assignee: Samsung Display Co., Ltd., Yongin-si (KR)

(21) Appl. No.: 19/468,197

(22) Filed: Feb. 3, 2026

(30) Foreign Application Priority Data
Apr. 10, 2025 (KR) 10-2025-0046538

(51) Int. Cl. H10K 59/80; H10H 29/01; H10H 29/37; H10H 29/80; H10K 59/12; H10K 59/122; H10K 102/00

(52) U.S. Cl. CPC H10K 59/877; H10H 29/012; H10H 29/37; H10H 29/882; H10K 59/1201; H10K 59/122; H10K 2102/351

(57) ABSTRACT

An electronic apparatus may include a display module including a light-emitting element and a pixel defining film including an opening. The light-emitting element may include a first electrode exposed through the opening, a scattering layer on the first electrode, an emission layer on the scattering layer, and a second electrode on the emission layer. The scattering layer may include a base portion and a plurality of hollow silica particles dispersed in the base portion, and including first and second hollow silica particles. The first hollow silica particle may be disposed on a top surface of the scattering layer spaced apart from the first electrode and may protrude from the top surface of the scattering layer toward the emission layer, and the second hollow silica particle may be disposed on the top surface of the scattering layer and may have an inner surface that is exposed.

### CROSS-REFERENCE TO RELATED APPLICATIONS

This U.S. non-provisional patent application claims priority under 35 U.S.C. § 119 of Korean Patent Application No. 10-2025-0046538, filed on Apr. 10, 2025, the entire contents of which are hereby incorporated by reference.

### BACKGROUND

Some example embodiments of the present disclosure herein relate to electronic apparatuses including a scattering layer including hollow silica particles, and/or methods for manufacturing the same.

As the information society advances, demands for display devices that display images are increasing in various ways. For example, display devices are applied to a wide range of electronic apparatuses such as smartphones, digital cameras, laptop computers, navigation systems, and smart televisions. A display device includes a display panel that generates images, and the display panel may be an organic light-emitting display panel. An organic light-emitting display panel includes a so-called self-emissive light-emitting element that realizes display by causing a light-emitting material of an emission layer to emit light, by recombination of holes and electrons injected from a first electrode and a second electrode in the emission layer. Studies are being conducted to improve the display quality of electronic apparatuses in consideration of the environments in which they are used.

### SUMMARY

Some example embodiments of the present disclosure provide electronic apparatuses that provide improved display quality.

Some example embodiments of the present disclosure provide methods for manufacturing an electronic apparatus that ensure improved processability.

An example embodiment of the inventive concepts, an electronic apparatus includes a display module including a light-emitting element and a pixel defining film including an opening, wherein the light-emitting element includes a first electrode exposed through the opening, a scattering layer on the first electrode, an emission layer on the scattering layer, and a second electrode on the emission layer, wherein the scattering layer includes a base portion and a plurality of hollow silica particles dispersed in the base portion, the plurality of hollow silica particles including a first hollow silica particle and a second hollow silica particles, wherein the first hollow silica particle is on a top surface of the scattering layer and protrudes from the top surface of the scattering layer toward the emission layer, the top surface of the scattering layer being spaced apart from the first electrode, and the second hollow silica particle is on the top surface of the scattering layer and has an exposed inner surface.

In an example embodiment, the second hollow silica particle may include a plurality of second hollow silica particles, and based on 100% of a total surface area of the top surface of the scattering layer, a sum of surface areas of the plurality of second hollow silica particles may be about 0.05% or more and about 20% or less.

In an example embodiment, each of the plurality of hollow silica particles may have a size of about 50 nm to about 200 nm.

In an example embodiment, based on a total weight of the scattering layer, a total weight of the plurality of hollow silica particles may be about 0.5 wt % or more and about 15 wt % or less.

In an example embodiment, the scattering layer may be in the opening of the pixel defining film.

In an example embodiment, the light-emitting element may further include a metal layer disposed between the scattering layer and the emission layer, wherein the metal layer may include at least one selected from Ag, Mg, Cu, Al, Pt, Pd, Au, Ni, Nd, Ir, Cr, Li, Ca, LiF, Mo, Ti, W, In, Sn, or Zn, a compound of two or more selected from Ag, Mg, Cu, Al, Pt, Pd, Au, Ni, Nd, Ir, Cr, Li, Ca, LiF, Mo, Ti, W, In, Sn, or Zn, a mixture of two or more selected from Ag, Mg, Cu, Al, Pt, Pd, Au, Ni, Nd, Ir, Cr, Li, Ca, LiF, Mo, Ti, W, In, Sn, or Zn, or an oxide of any one of Ag, Mg, Cu, Al, Pt, Pd, Au, Ni, Nd, Ir, Cr, Li, Ca, LiF, Mo, Ti, W, In, Sn, or Zn.

In an example embodiment, the metal layer may be directly on the scattering layer.

In an example embodiment, the metal layer may have a thickness of about 200 Å to about 500 Å.

In an example embodiment, the metal layer may be in the opening of the pixel defining film.

In an example embodiment, the plurality of hollow silica particles may further include third hollow silica particles that do not protrude from the top surface of the scattering layer toward the emission layer and do not have exposed inner surfaces.

In an example embodiment, the base portion may include an organic material.

In an example embodiment, the electronic apparatus may further include at least one of a processor, power supply circuitry, or a memory.

In an example embodiment of the inventive concepts, a method for manufacturing an electronic apparatus includes preparing a base layer, forming a first electrode on the base layer, forming a pixel defining film having an opening through which the first electrode is exposed, forming a scattering layer on the first electrode, forming an emission layer on the scattering layer, and forming a second electrode on the emission layer, wherein the forming of the scattering layer includes forming a preliminary scattering layer on the first electrode, the preliminary scattering layer including a preliminary base portion and a plurality of preliminary hollow silica particles dispersed in the preliminary base portion, and treating the preliminary scattering layer with plasma to form the scattering layer including a base portion and a plurality of hollow silica particles that are formed from the preliminary base portion and the plurality of preliminary hollow silica particles, respectively, wherein the plurality of hollow silica particles include a first hollow silica particles and a second hollow silica particle, wherein the first hollow silica particle is disposed on a top surface of the scattering layer and protrudes toward the emission layer from the top surface of the scattering layer, the top surface of the scattering layer being spaced apart from the first electrode, and the second hollow silica particle is disposed on the top surface of the scattering layer and has an exposed inner surfaces.

In an example embodiment, the plasma may include fluorine plasma or oxygen plasma.

In an example embodiment, the preliminary base portion may be etched in the treating of the plasma.

In an example embodiment, a total weight of the plurality of hollow silica particles may be about 0.5 wt % or more and about 15 wt % or less based on a total weight of the scattering layer.

In an example embodiment, each of the plurality of hollow silica particles may have a size of about 50 nm to about 200 nm.

In an example embodiment, the preliminary scattering layer may be formed by an inkjet printing method or a photolithography method.

In an example embodiment, the method may further include forming a metal layer on the scattering layer between the forming of the scattering layer and the forming of the emission layer, wherein the metal layer may include at least one selected from the group consisting of Ag, Mg, Cu, Al, Pt, Pd, Au, Ni, Nd, Ir, Cr, Li, Ca, LiF, Mo, Ti, W, In, Sn, and Zn, compounds of two or more selected from the group consisting of Ag, Mg, Cu, Al, Pt, Pd, Au, Ni, Nd, Ir, Cr, Li, Ca, LiF, Mo, Ti, W, In, Sn, and Zn, mixtures of two or more selected from the group consisting of Ag, Mg, Cu, Al, Pt, Pd, Au, Ni, Nd, Ir, Cr, Li, Ca, LiF, Mo, Ti, W, In, Sn, and Zn, or oxides of any one selected from the group consisting of Ag, Mg, Cu, Al, Pt, Pd, Au, Ni, Nd, Ir, Cr, Li, Ca, LiF, Mo, Ti, W, In, Sn, and Zn.

In an example embodiment, the method may further include performing an ashing process on the metal layer before the forming of the emission layer.

### BRIEF DESCRIPTION OF THE FIGURES

The accompanying drawings are included to provide a further understanding of the inventive concepts, and are incorporated in and constitute a part of this specification. The drawings illustrate some example embodiments of the inventive concepts and, together with the description, serve to explain principles of the inventive concepts. In the drawings:

FIG. 1 is a block diagram of an electronic apparatus according to an example embodiment;

FIG. 2 is a view of electronic apparatuses according to various example embodiments;

FIG. 3 is a perspective view of an electronic apparatus according to an example embodiment of the inventive concepts;

FIG. 4 is an exploded perspective view of the electronic apparatus according to an example embodiment of the inventive concepts;

FIG. 5 is a cross-sectional view taken along line I-I′ of FIG. 4;

FIG. 6 is a plan view showing a portion of the electronic apparatus according to an example embodiment;

FIG. 7A is a cross-sectional view showing a portion of the electronic apparatus according to an example embodiment;

FIG. 7B is a perspective view showing a portion of the electronic apparatus according to an example embodiment;

FIG. 7C is a cross-sectional view showing a portion of an electronic apparatus according to an example embodiment;

FIG. 8A is a flowchart illustrating a method for manufacturing an electronic apparatus according to an example embodiment;

FIG. 8B is a flowchart illustrating a method for manufacturing the electronic apparatus according to an example embodiment;

FIG. 9 is a diagram schematically illustrating an operation for manufacturing an electronic apparatus according to an example embodiment;

FIG. 10 is a diagram schematically illustrating the step for manufacturing the electronic apparatus according to an example embodiment;

FIG. 11 is a diagram schematically illustrating the step for manufacturing the electronic apparatus according to an example embodiment;

FIG. 12 is a diagram schematically illustrating the step for manufacturing the electronic apparatus according to an example embodiment;

FIG. 13 is a diagram schematically illustrating the step for manufacturing the electronic apparatus according to an example embodiment;

FIG. 14A is an image showing a pixel defining film in an experimental example;

FIG. 14B is an image showing a pixel defining film in an experimental example;

FIG. 14C is an image showing a pixel defining film in an experimental example; and

FIG. 14D is an image showing a pixel defining film in an experimental example.

### DETAILED DESCRIPTION

Because the present disclosure may have diverse modified example embodiments, specific example embodiments are illustrated in the drawings and are described in the detailed description of the inventive concepts. However, this does not limit the present disclosure within the specific example embodiments and it should be understood that the present disclosure covers all the modifications, equivalents, and replacements within the idea and technical scope of the present disclosure.

In this specification, it will also be understood that when one component (or region, layer, portion) is referred to as being ‘on’, ‘connected to’, or ‘coupled to’ another component, it can be directly disposed/connected/coupled on/to the one component, or an intervening third component may also be present.

Like reference numerals refer to like elements throughout. Also, in the figures, the thickness, ratio, and dimensions of components are exaggerated for clarity of illustration. The term “and/or” includes any and all combinations of one or more of the associated components.

The terms such as first and second may be used to describe various components, but the components should not be limited by these term. The terms are used solely for the purpose of distinguishing one component, part, area, layer, or portion from another component, part, area, layer, or portion. For example, without departing from the scope of the inventive concepts, a first component, first part, first area, first layer, or first portion may be referred to as a second component, second part, second area, second layer, or second portion, and similarly, a second component, second part, second area, second layer, or second portion may be referred to as a first component, first part, first area, first layer, or first portion. The singular forms include the plural forms as well, unless the context clearly indicates otherwise.

Also, “under”, “below”, “above”, “upper”, and the like are used for explaining relation association of components illustrated in the drawings. The terms may be a relative concept and described based on directions expressed in the drawings.

It will be understood that the term “include” or “comprise”, when used in this specification, specifies the presence of stated features, integers, steps, operations, elements, components, or a combination thereof, but does not preclude the presence or addition of one or more other features, integers, steps, operations, elements, components, or combinations thereof.

As used herein, expressions such as “one of,” “one or more of,” “any one of,” “at least one of,” “at least one selected from,” and “two or more selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Unless otherwise defined, all terms (including technical and scientific terms) used herein have the same meaning as commonly understood by a person of ordinary skill in the art to which this inventive concepts belong. In addition, terms such as those defined in commonly used dictionaries should be interpreted as having meanings consistent with their meanings in the context of the relevant technology, and unless explicitly defined, it should not be interpreted in an overly idealistic or overly formal sense.

Hereinafter, some example embodiments of the inventive concepts will be described with reference to the accompanying drawings.

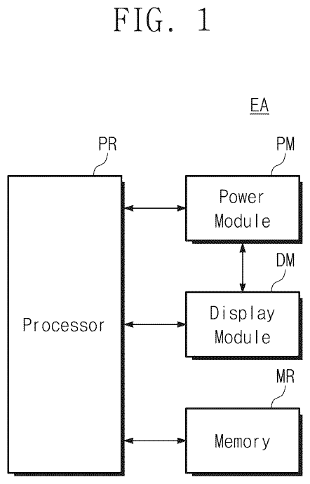

FIG. 1 is a block diagram of an electronic apparatus according to an example embodiment. An electronic apparatus EA may include a display module DM. The electronic apparatus EA may further include at least one of a processor PR, a memory MR, or a power module (or power supply circuitry) PM. Referring to FIG. 1, an electronic apparatus EA according to an example embodiment may include the display module (or display) DM, the processor PR, the memory MR, and the power module PM.

The processor PR may include at least one of a central processing unit CPU, an application processor AP, a graphic processing unit GPU, a communication processor CP, an image signal processor ISP, or a controller.

The memory MR may store data information desired for the operation of a processor PR or a display module DM. When the processor PR executes an application stored in the memory MR, image data signals and/or input control signals may be transmitted to the display module DM, and the display module DM may process the received signals to output image information through a display screen.

A power module PM may include a power supply module, such as a power adapter or a battery device, and a power conversion module configured to convert power supplied by the power supply module to generate power desired for operating the electronic apparatus EA.

At least one of the components of the above-described electronic apparatus EA may be included in a display device according to the example embodiments described below. In addition, a part of the individual modules functionally included in a single module may be included in the display device, and the other part may be provided separately from the display device. For example, the display device may include the display module DM, and the processor PR, the memory MR, and the power module PM may be provided in the type of other devices within the electronic apparatus EA, rather than in the display device.

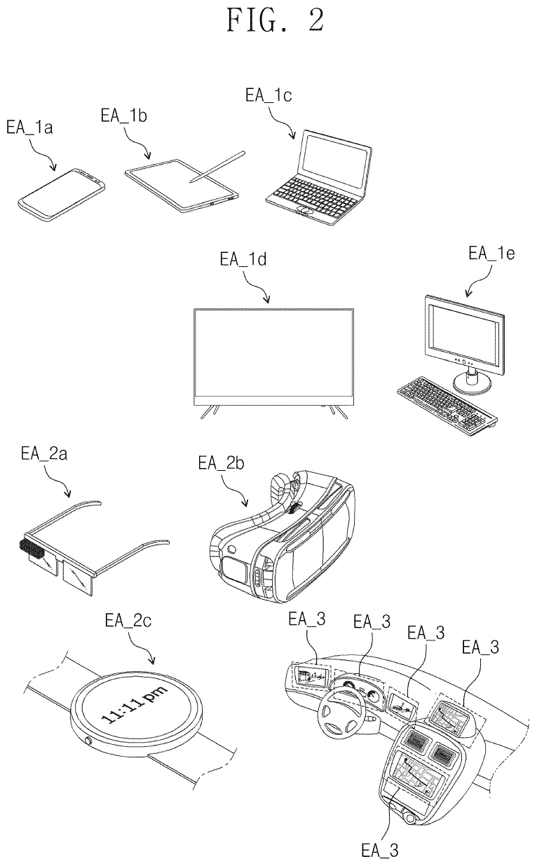

FIG. 2 is a schematic diagram of electronic apparatuses according to various example embodiments. Referring to FIG. 2, various electronic devices to which the display device according to the example embodiments is applied may include image display electronic apparatuses such as a smartphone EA_1a, a tablet PC EA_1b, a laptop EA_1c, a TV EA_1d, and a desktop monitor EA_1e; wearable electronic apparatuses including a display module, such as smart glasses EA_2a, a head-mounted display EA_2b, and a smart watch EA_2c; and vehicle electronic devices EA_3 including display modules, such as a CID (Center Information Display) and a room mirror display, which are disposed on a cluster, center fascia, or dashboard of a vehicle.

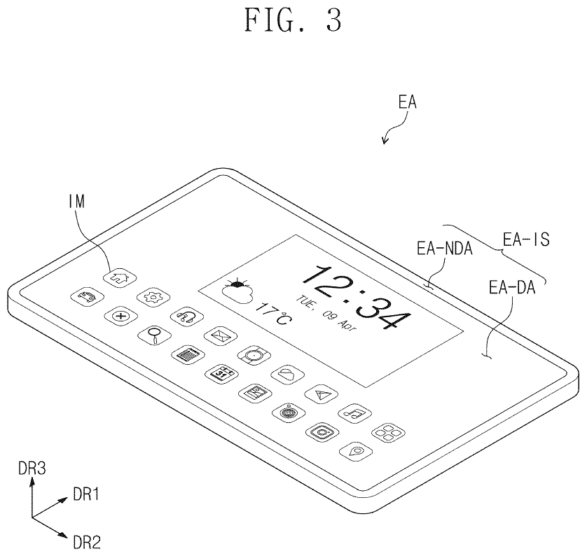

FIG. 3 is a perspective view of an electronic apparatus according to an example embodiment of the inventive concepts. The electronic apparatus EA of the example embodiment shown in FIG. 3 may be a device activated according to electrical signals. For example, the electronic apparatus EA may be a tablet PC, personal computer, laptop computer, personal digital assistant, game console, portable electronic device, television, monitor, outdoor advertisement board, in-vehicle navigation system, or wearable devices, but example embodiment is not limited thereto. In FIG. 3, a tablet PC is illustrated as an example of the electronic apparatus EA.

The electronic apparatus EA may provide an image IM to a user through a display surface EA-IS. The display surface EA-IS may be parallel to a plane defined by a first direction axis DR1 and a second direction axis DR2. The electronic apparatus EA may display the image IM in a third direction axis DR3. The image IM may include dynamic images and/or static images. FIG. 3 illustrates the electronic apparatus EA having the flat display surface EA-IS, but example embodiments are not limited thereto. For example, the electronic apparatus EA may include a curved display surface or a three-dimensional display surface. The solid display surface may include a plurality of display areas that indicate different directions.

The directions indicated as the first to third direction axes DR1, DR2, and DR3, which are described in this specification, may be a relative concept and thus changed into different directions. In addition, the directions indicated by the first to third direction axes DR1, DR2, and DR3 may be described as first to third directions, and also, the same reference numerals may be used.

In this specification, the first direction axis DR1 and the second direction axis DR2 may be perpendicular to each other. A third direction axis DR3 may be a normal direction with respect to a plane defined by the first direction DR1 and the second direction DR2. A thickness direction of the electronic apparatus EA may be parallel to the third direction axis DR3. The thickness direction of the electronic apparatus EA may be denoted by the same reference symbol DR3 as the third direction axis. A front surface (or top surface) and a rear surface (or bottom surface) may be opposed to each other in the third direction axis DR3, and normal directions of the front surface (or top surface) and the rear surface (or bottom surface) may be parallel to the third direction axis DR3. The front surface (or top surface) may refer to a surface adjacent to the display surface EA-IS, and the rear surface (or bottom surface) may refer to a surface spaced apart from the display surface EA-IS. An upper side may refer to a direction approaching the display surface EA-IS, and the lower side may refer to a direction away from the display surface EA-IS.

In the present specification, a cross-sectional surface refers to a surface parallel to the thickness direction DR3. A planar surface refers to a surface perpendicular to the thickness direction DR3 and parallel to a plane defined by the first direction axis DR1 and the second direction axis DR2.

In the present specification, when one component overlaps another component, it means that they overlap in a planar view (e.g., in plan view). In addition, the overlap between one component and another component is not limited to cases in which they have the same surface area and the same shape, and may include cases in which they have different surface areas and/or different shapes.

In the present specification, when one component is directly disposed/provided on another component, it means that no third component is interposed between the one component and the other component. That is, the direct disposition/provision of one component on another component means that the two components are in contact with each other.

The electronic apparatus EA may detect an external input applied from outside. The external input may include various types of inputs provided from outside the electronic apparatus EA. For example, an external input may include not only contact by a part of a human body such as a user's hand, but also external input applied by approaching or being adjacent to the electronic apparatus EA at a desired (or alternatively, predetermined) distance (e.g., hovering). In addition, the external input may have various forms such as force, pressure, temperature, or light.

The display surface EA-IS may include a display area EA-DA and a non-display area EA-NDA. The electronic apparatus EA may display the image IM through the display area EA-DA.

A display area EA-DA may be an area activated according to an electrical signal. The display area EA-DA may be an area in which an image IM is displayed and various types of external input may be sensed.

The display area EA-DA may include a plane defined by a first direction axis DR1 and a second direction axis DR2. Unlike what is illustrated, the display area EA-DA may include a curved surface bent from at least one side of the plane defined by the first direction axis DR1 and the second direction axis DR2. For example, the display area EA-DA may further include four curved surfaces bent from four sides of the plane defined by the first direction axis DR1 and the second direction axis DR2, respectively.

The electronic apparatus EA of an example embodiment may be flexible. The “flexible” means a bendable property and may include anything from a completely foldable structure to a structure that is capable of bend at a level of a few nanometers. For example, the electronic apparatus EA may be a rigid device. In some example embodiments, the electronic apparatus EA may be a foldable device.

A non-display area EA-NDA may have a desired (or alternatively, predetermined) color. The non-display area EA-NDA may be an area adjacent to the display area EA-DA. The non-display area EA-NDA may surround the display area EA-DA. Accordingly, a shape of the display area EA-DA may be substantially defined by the non-display area EA-NDA. However, FIG. 3 is merely an illustrative example, and the non-display area EA-NDA may be disposed adjacent to only one side of the display area EA-DA or may be omitted. The display area EA-DA may be provided in various shapes and is not limited to any one example embodiment.

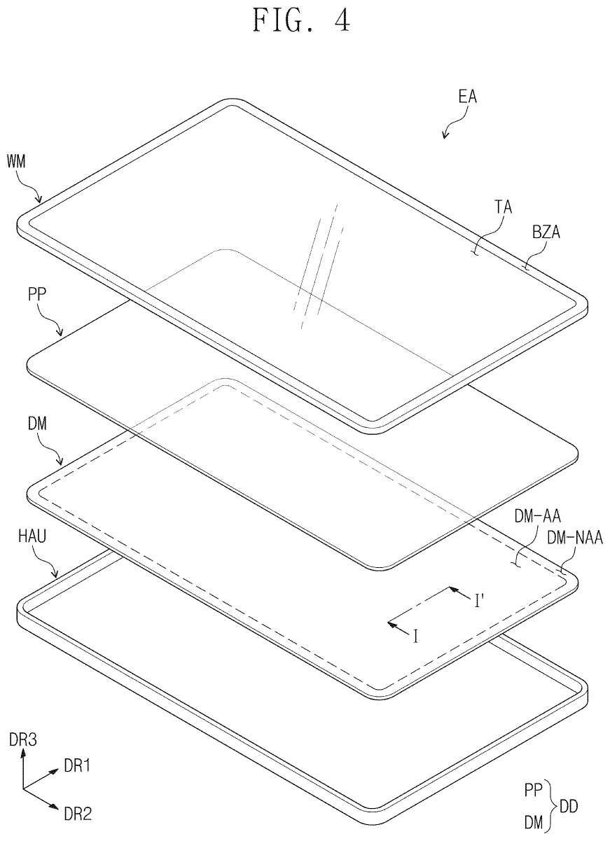

FIG. 4 is an exploded perspective view of the electronic apparatus according to an example embodiment of the inventive concepts; Referring to FIG. 4, the electronic apparatus EA may include a display device DD. In addition, the electronic apparatus EA may further include a window member WM and a housing HAU.

The window member WM may be disposed on the display device DD. The window member WM may cover the entire outer side of the electronic apparatus EA. The window member WM may include a transmission area TA and a bezel area BZA. The front surface of the window member WM including a transmission area TA and a bezel area BZA may correspond to the front surface of the electronic apparatus EA. The transmission area TA may correspond to the display area EA-DA of the electronic apparatus EA illustrated in FIG. 3, and the bezel area BZA may correspond to the non-display area EA-NDA of the electronic apparatus EA illustrated in FIG. 3.

The transmission area TA may be an optically transparent area. The bezel area BZA may be an area having light transmittance that is relatively less than that of the transmission area TA. The bezel area BZA may have a desired (or alternatively, predetermined) color. The bezel area BZA may be disposed adjacent to the transmission area TA and surround the transmission area TA. The bezel area BZA may define a shape of the transmission area TA. However, example embodiments are not limited as being illustrated, and the bezel area BZA may be disposed adjacent to only one side of the transmission area TA, or a portion of the bezel area BZA may be omitted.

The housing HAU may include a material having relatively high rigidity. For example, the housing HAU may include a frame and/or plate made of glass, plastic, or metal. The frame and/or plate may be provided in plurality. The housing HAU may provide a desired (or alternatively, predetermined) accommodation space. The display device DD may be accommodated within an accommodation space and protected from an external impact.

The display device DD may include the display module DM and an optical layer PP disposed on the display module DM. The display module DM may be activated according to an electrical signal and may provide an image IM (see FIG. 3). The display module DM may be activated to display the image IM (see FIG. 3) in the display area EA-DA (see FIG. 3) of the electronic apparatus EA. An active area DM-AA and a non-active area DM-NAA may be defined in the display module DM.

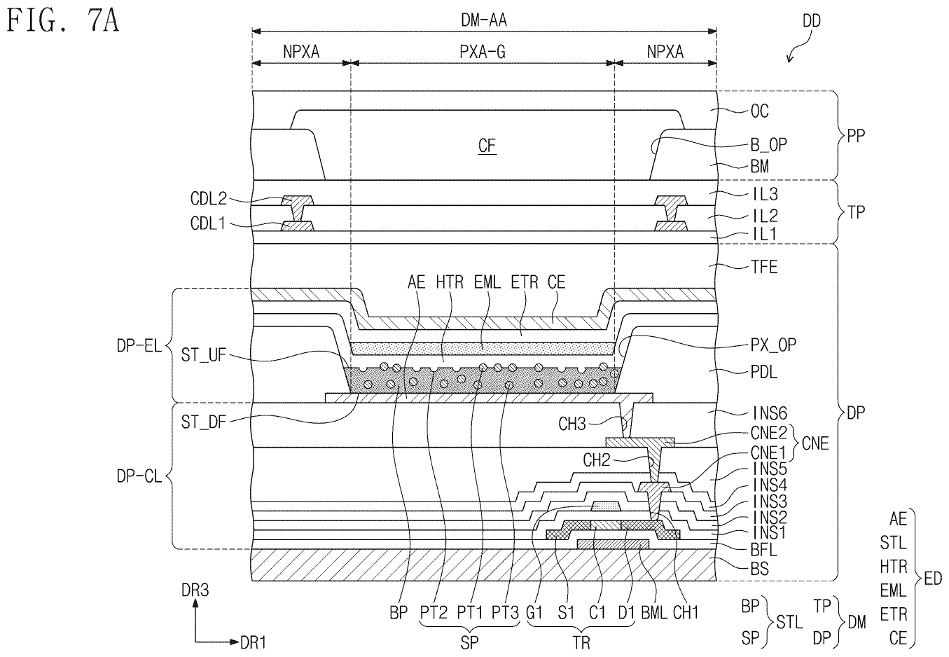

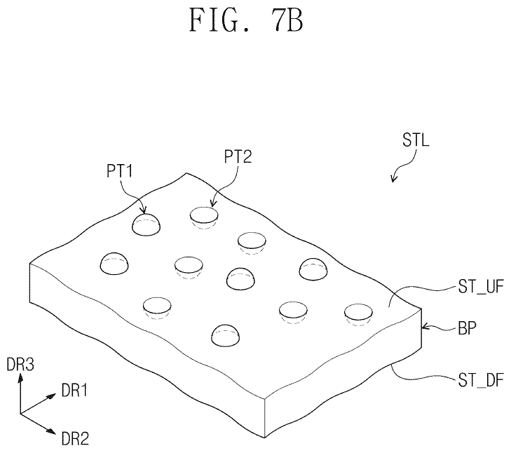

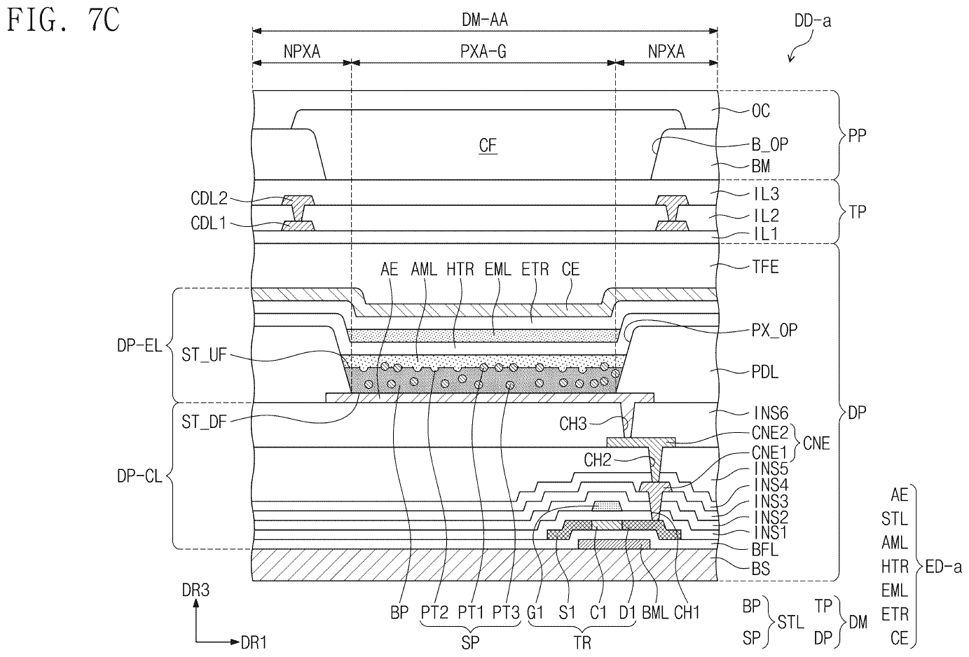

The active area DM-AA may be an area that is activated by an electrical signal. Pixels (not shown) may be disposed in the active area DM-AA. The pixels may include a transistor TR (see FIG. 7A) and a light-emitting element ED (see FIG. 7A). The non-active area DM-NAA may be an area located adjacent to at least one side of the active area DM-AA. A circuit or line for driving the active area DM-AA may be disposed in the non-active area DM-NAA.

The optical layer PP may be a layer that reduces reflectance due to external light incident from outside. In addition, the optical layer PP may transmit source light emitted from the display module DM or convert a wavelength of the source light. The optical layer PP may be disposed on the display module DM through a continuous process. The optical layer PP may include a polarizing plate or may include a color filter layer. For example, the optical layer PP may include at least one of a retarder, a polarizer, a polarizing film, or a polarizing filter. In some example embodiments, the optical layer PP may include a plurality of color filters arranged in a desired (or alternatively, predetermined) pattern and a black matrix adjacent to the color filters. Unlike what is illustrated, the optical layer PP may be omitted.

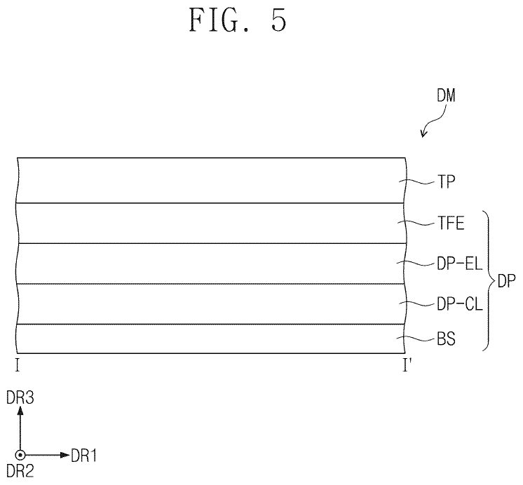

FIG. 5 is a cross-sectional view taken along line I-I′ of FIG. 4. FIG. 5 may be a cross-sectional view illustrating the display module DM according to an example embodiment.

Referring to FIG. 5, the display module DM may include a display panel DP and an input sensing layer TP disposed on the display panel DP. The display panel DP may include a base layer BS, a circuit layer DP-CL disposed on the base layer BS, a display element layer DP-EL disposed on the circuit layer DP-CL, and an encapsulation layer TFE disposed on the display element layer DP-EL.

The display panel DP may be a configuration that actually generates an image. The display panel DP may be a light-emitting display panel. For example, the display panel DP may be an organic light-emitting display panel. In some example embodiments, the display panel DP may be a quantum dot light-emitting display panel including a quantum dot light-emitting element. The display panel DP may emit source light.

The base layer BS may be a member that provides a base surface on which the circuit layer DP-CL is disposed. The base layer BS may be a rigid substrate or a flexible substrate that may undergo bending, folding, or rolling. The base layer BS may be a glass substrate, a metal substrate, or a polymer substrate. However, example embodiments are not limited thereto, and the base layer BS may be an inorganic layer, an organic layer, or a composite material layer.

The circuit layer DP-CL may be disposed on the base layer BS. The circuit layer DP-CL may include an insulating layer, a semiconductor pattern, a conductive pattern, and a signal line. After an insulating layer, a semiconductor layer, and a conductive layer are provided on the base layer BS by coating, deposition process, or the like, the insulating layer, semiconductor layer, and conductive layer may be selectively patterned through multiple photolithography processes. Subsequently, a semiconductor pattern, a conductive pattern, and signal lines included in the circuit layer DP-CL may be provided.

The display element layer DP-EL may be disposed on the circuit layer DP-CL. The display element layer DP-EL may include a pixel defining film PDL (see FIG. 7A) and a light-emitting element ED (see FIG. 7A), which will be described later. In the display module DM, the light-emitting element ED (see FIG. 7A) may emit source light. For example, the display element layer DP-EL may include an organic light-emitting material, an inorganic light-emitting material, an organic-inorganic hybrid light-emitting material, quantum dots, or quantum rods. For example, the display element layer DP-EL may include micro LEDs or nano LEDs.

The encapsulation layer TFE may protect the display element layer DP-EL from foreign substances such as moisture, oxygen, and/or dust particles. The encapsulation layer TFE may include at least one inorganic layer. The encapsulation layer TFE may include a structure in which an inorganic layer, an organic layer, and an inorganic layer are sequentially laminated.

The input sensing layer TP may detect an external input, convert the input into a desired (or alternatively, predetermined) input signal, and provide the input signal to the display panel DP. For example, the input sensing layer TP may be a touch sensing layer that detects a touch. The input sensing layer TP may recognize a direct touch of a user, an indirect touch of a user, a direct touch of an object, and/or an indirect touch of an object.

The input sensing layer TP may detect at least one of a position of a touch or an intensity (pressure) of the touch applied from the outside. The input sensing layer TP may have various structures or be made of various materials, and is not limited to any one example embodiment. For example, the input sensing layer TP may detect an external input using a capacitive method. The display panel DP may receive an input signal from the input sensing layer TP and may generate an image corresponding to the input signal.

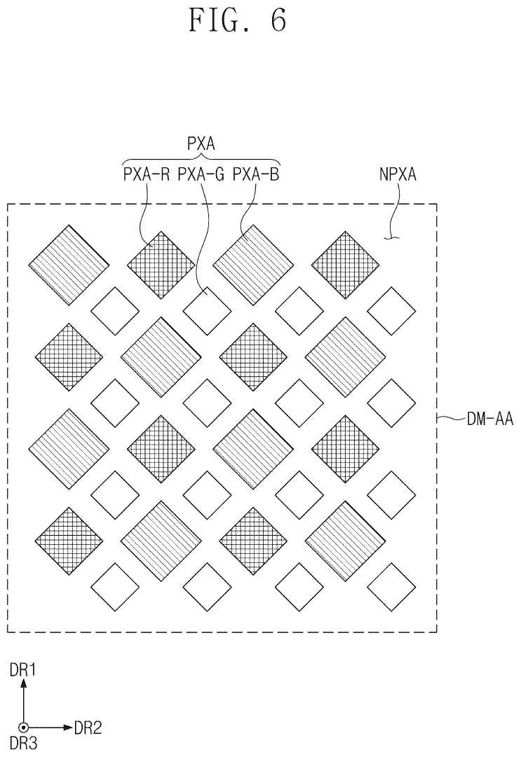

FIG. 6 is an enlarged plan view showing a portion of the active area according to an example embodiment. Referring to FIG. 6, the active area DM-AA may include a light-emitting area PXA and a light-blocking area NPXA. The light-blocking area NPXA may surround the light-emitting area PXA.

The light-emitting area PXA may be provided as a plurality of light-emitting areas that emit light in different wavelength ranges. The light-emitting area PXA may include a first light-emitting area PXA-B, a second light-emitting area PXA-G, and a third light-emitting area PXA-R. For example, the first light-emitting area PXA-B may emit blue light, the second light-emitting area PXA-G may emit green light, and the third light-emitting area PXA-R may emit red light. However, example embodiments are not limited thereto, and the first to third light-emitting areas PXA-B, PXA-G, and PXA-R may emit light of colors other than blue, green, and red.

In the light-emitting areas PXA, a surface area of the first light-emitting area PXA-B, which emits blue light, may be the largest, and a surface area of the second light-emitting area PXA-G, which emits green light, may be the smallest. Here, the surface area refers to a planar surface area. However, this is merely an example, and the surface areas of the first to third light-emitting areas PXA-B, PXA-G, and PXA-R are not limited thereto.

In FIG. 6, the first light-emitting area PXA-B and the third light-emitting area PXA-R are alternately arranged in a first row along the second direction DR2, and the second light-emitting area PXA-G is arranged in a second row spaced apart from the first light-emitting area PXA-B and the third light-emitting area PXA-R. However, this is merely an example, and the arrangement of the first to third light-emitting areas PXA-B, PXA-G, and PXA-R is not limited thereto. In addition, the planar shapes of the first to third light-emitting areas PXA-B, PXA-G, and PXA-R are not limited to those illustrated, and may be defined in different shapes.

The light-blocking area NPXA may be an area between neighboring light-emitting areas PXA-B, PXA-G, and PXA-R, and may correspond to a pixel defining film PDL (see FIG. 7A), which will be described later. The light-emitting area PXA may correspond to a light-emitting element ED (see FIG. 7A), which will be described later.

FIG. 7A is a cross-sectional view specifically illustrating a display device DD according to an example embodiment. FIG. 7A may also be a cross-sectional view corresponding to the second light-emitting area PXA-G and an adjacent light-blocking area NPXA shown in FIG. 6. Hereinafter, the description of the second light-emitting area PXA-G may be equally applied to the first and third light-emitting areas PXA-B and PXA-R shown in FIG. 6.

Referring to FIG. 7A, the base layer BS may include a single layer or a multilayer structure. For example, the base layer BS may include a first synthetic resin layer, a multilayer or single inorganic layer, and a second synthetic resin layer disposed on the multilayer or single inorganic layer. Each of the first synthetic resin layer and the second synthetic resin layer may include a polyimide-based resin. In addition, each of the first synthetic resin layer and the second synthetic resin layer may include at least one of an acryl-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, the “~~-based” resin means containing a “~~” functional group.

The display panel DP may include a transistor TR and a light-emitting element ED. The transistor TR and the light-emitting element ED may be disposed on the base layer BS. Although only one transistor TR is illustrated in FIG. 7A, the display panel DP may substantially include a plurality of transistors for driving the light-emitting element ED and at least one capacitor.

The circuit layer DP-CL may include an insulating layer, a semiconductor pattern, a conductive pattern, and a signal line. For example, the circuit layer DP-CL may include a switching transistor and a driving transistor for driving the light-emitting element ED of the display element layer DP-EL.

The circuit layer DP-CL may include a shielding electrode BML, a transistor TR, a connection electrode CNE, and a plurality of insulating layers BFL and INS1 to INS6. The plurality of insulating layers BFL and INS1 to INS6 may include a buffer layer BFL and first to sixth insulating layers INS1 to INS6. However, the laminated structure of the circuit layer DP-CL shown in FIG. 7A is merely illustrative, and the laminated structure of the circuit layer DP-CL may vary depending on the configuration of the display panel DP or the process of the circuit layer DP-CL.

A shielding electrode BML may be disposed on the base layer BS. The shielding electrode BML may overlap the transistor TR. The shielding electrode BML may protect the transistor TR by blocking light incident onto the transistor TR from a lower portion of the display panel DP. The shielding electrode BML may include a conductive material. When a voltage is applied to the shielding electrode BML, a threshold voltage of the transistor TR disposed on the shielding electrode BML may be maintained. However, example embodiments are not limited thereto, and the shielding electrode BML may be a floating electrode. The shielding electrode BML may be omitted.

The buffer layer BFL may be disposed on the base layer BS to cover the shielding electrode BML. The buffer layer BFL may include an inorganic layer. The buffer layer BFL may enhance adhesion force between the semiconductor pattern or conductive pattern disposed on the buffer layer BFL and the base layer BS.

The transistor TR may include a source S1, a channel C1, a drain D1, and a gate G1. The source S1, the channel C1, and the drain D1 of the transistor TR may be provided from the semiconductor pattern. The semiconductor pattern of the transistor TR may include polysilicon, amorphous silicon, or metal oxide, and if the semiconductor pattern has any semiconductor property, any materials may be applied without limitation and is not limited to any one.

The semiconductor pattern may include a plurality of regions that are distinguished by their conductivity magnitudes. In the semiconductor patterns, a doped region with dopants or a region where a metal oxide is reduced may have relatively high conductivity, and may substantially serve as a source electrode and a drain electrode of the transistor TR. The relatively highly doped region in the semiconductor patterns may correspond to a source S1 and a drain D1 of the transistor TR. A non-doped region, a relatively lightly doped region, or a region where a metal oxide remains unreduced with relatively low conductivity of the semiconductor patterns may correspond to a channel C1 (or active region) of the transistor TR.

The first insulating layer INS1 may cover the semiconductor pattern of the transistor TR and may be disposed on the buffer layer BFL. The gate G1 of the transistor TR may be disposed on the first insulating layer INS1. In a planar view, the gate G1 may overlap the channel C1 of the transistor TR. The gate G1 may function as a mask in a process of doping the semiconductor pattern of the transistor TR.

The second insulating layer INS2 may cover the gate G1 and may be disposed on the first insulating layer INS1. The third insulating layer INS3 may be disposed on the second insulating layer INS2.

A connection electrode CNE may include a first connection electrode CNE1 and a second connection electrode CNE2 for electrically connecting the transistor TR and the light-emitting element ED. However, the configuration of the connection electrode CNE for electrically connecting the transistor TR and the light-emitting element ED is not limited thereto, and either the first or second connection electrode CNE1 or CNE2 may be omitted, or an additional connection electrode may be further included.

The first connection electrode CNE1 may be disposed on the third insulating layer INS3. The first connection electrode CNE1 may be connected to the drain D1 through a first contact hole CH1 passing through the first to third insulating layers INS1 to INS3. The fourth insulating layer INS4 may cover the first connection electrode CNE1 and may be disposed on the third insulating layer INS3. The fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 through a second contact hole CH2 passing through the fourth and fifth insulating layers INS4 and INS5. The sixth insulating layer INS6 may cover the second connection electrode CNE2 and may be disposed on the fifth insulating layer INS5.

Each of the first to sixth insulating layers INS1 to INS6 may include an inorganic layer or an organic layer. For example, the inorganic layer may include at least one of aluminum oxide, titanium oxide, silicon oxide, silicon oxynitride, zirconium oxide, or hafnium oxide. The organic layer may include at least one of acrylic resin, methacrylic resin, polyisoprene resin, vinyl resin, epoxy resin, urethane resin, cellulose resin, siloxane resin, polyamide resin, or parylene resin.

The display element layer DP-EL may include the pixel defining film PDL and the light-emitting element ED. The pixel defining film PDL may be disposed on the sixth insulating layer INS6. The pixel defining film PDL may define an opening PX_OP that exposes a portion of a first electrode AE. The portion of the first electrode AE exposed through the opening PX_OP may be defined as a second light-emitting area PXA-G. An area on which the pixel defining film PDL is disposed may correspond to the light-blocking area NPXA.

The pixel defining film PDL may be made of a polymer resin. For example, the pixel defining film PDL may include a polyacrylate-based resin or a polyimide-based resin. Also, the pixel defining film PDL may further include an inorganic material in addition to the polymer resin. The pixel defining film PDL may be provided by including a light-absorbing material, or by including a black pigment or a black dye. The pixel defining film PDL including a black pigment or a black dye may implement a black pixel defining film. As the black pigment or black dye used for forming the pixel defining film PDL, carbon black may be used, but example embodiments are not limited thereto.

In addition, the pixel defining film PDL may be composed of or include an inorganic material. For example, the pixel defining film PDL may be composed of an inorganic material such as silicon nitride (SiNₓ), silicon oxide (SiOₓ), or silicon oxynitride (SiOₓN_{y}).

The light-emitting element ED may allow Lambertian reflection. Lambertian reflection refers to a phenomenon in which the luminance appears constant regardless of the viewing angle of the observer.

The light-emitting element ED may include a first electrode AE, a scattering layer STL disposed on the first electrode AE, an emission layer EML disposed on the scattering layer STL, and a second electrode CE disposed on the emission layer EML. The light-emitting element ED may further include a hole transport region HTR disposed between the scattering layer STL and the emission layer EML, and an electron transport region ETR disposed between the emission layer EML and the second electrode CE.

The first electrode AE may be made of a metal material, a metal alloy, or a conductive compound. The first electrode AE may be an anode or a cathode. However, example embodiments of the inventive concepts are not limited thereto. In addition, the first electrode AE may be a pixel electrode. The first electrode AE may be a transmissive electrode, a transflective electrode, or a reflective electrode. The first electrode AE may include at least one selected from (or at least one of) Ag, Mg, Cu, Al, Pt, Pd, Au, Ni, Nd, Ir, Cr, Li, Ca, LiF, Mo, Ti, W, In, Sn, or Zn, a compound of two or more selected therefrom, a mixture of two or more selected therefrom, or an oxide of any one thereof.

When the first electrode AE is the transmissive electrode, the first electrode AE may include transparent metal oxide, for example, indium tin oxide (ITO), indium zinc oxide (IZO), zinc oxide (ZnO), or indium tin zinc oxide (ITZO). When the first electrode AE is the transflective electrode or the reflective electrode, the first electrode AE may include Ag, Mg, Cu, Al, Pt, Pd, Au, Ni, Nd, Ir, Cr, Li, Ca, LiF/Ca (laminated structure of LiF and Ca), LiF/Al (laminated structure of LiF and Al), Mo, Ti, W, or a compound or mixture thereof (e.g., a mixture of Ag and Mg). In some example embodiments, the first electrode AE may have a multi-layered structure including a reflective layer or transflective layer and a transparent conductive layer made of indium tin oxide (ITO), indium zinc oxide (IZO), zinc oxide (ZnO), or indium tin zinc oxide (ITZO). For example, the first electrode AE may have a three-layer structure of ITO/Ag/ITO, but is not limited thereto. In addition, example embodiments are not limited thereto, and the first electrode AE may include the above-described metal materials, a combination of two or more metal materials of the above-described metal materials, or oxide of the above-described metal materials. The first electrode AE may have a thickness in the range of about 700 Å to about 10000 Å. For example, the thickness of the first electrode AE may be in the range of about 1000 Å to about 3000 Å.

A scattering layer STL may be disposed in an opening PX_OP of the pixel defining film PDL. The scattering layer STL may be in contact with an inner surface of the pixel defining film PDL that defines the opening PX_OP. For example, in a thickness direction DR3, the scattering layer STL may have a thickness in the range of about 200 nm to about 1000 nm.

In one example embodiment, the scattering layer STL may include a base portion BP and a plurality of hollow silica particles SP dispersed in the base portion BP. The base portion BP may be optically transparent. The base portion BP may serve as a medium in which the hollow silica particles SP are dispersed and may be made of or include various resin compositions. The base portion BP may include an organic material. For example, the base portion BP may include an acrylic resin. However, this is merely an example, and the base portion BP may be composed of any organic material that is optically transparent and allows easy dispersion of the hollow silica particles SP.

Light incident on the scattering layer STL may be scattered by the hollow silica particles SP. The hollow silica particles SP may serve as scattering elements. The hollow silica particles SP may include a first hollow silica particle PT1 and a second hollow silica particle PT2. The first hollow silica particle PT1 and the second hollow silica particle PT2 may be located at a top surface ST_UF of the scattering layer STL.

The scattering layer STL may be directly disposed on the first electrode AE. The scattering layer STL may include the top surface ST_UF and a bottom surface ST_DF. The top surface ST_UF and the bottom surface ST_DF may be integrally shaped. The top surface ST_UF and the bottom surface ST_DF may face each other in the thickness direction DR3. The upper surface ST_UF may be spaced apart from the first electrode AE. The lower surface ST_DF may be disposed between the upper surface ST_UF and the first electrode AE. The lower surface ST_DF may be spaced apart from an emission layer EML. The upper surface ST_UF may be disposed between the lower surface ST_DF and the emission layer EML. The first hollow silica particle PT1 and the second hollow silica particle PT2 may not be located at the lower surface ST_DF of the scattering layer STL.

In the thickness direction DR3, the scattering layer STL may be divided into a first portion, a second portion, and a third portion. The first portion may include the upper surface ST_UF of the scattering layer STL. The second portion may include the lower surface ST_DF of the scattering layer STL. The third portion may be located between the first portion and the second portion, and may not include the upper surface ST_UF or the lower surface ST_DF. The first hollow silica particle PT1 and the second hollow silica particle PT2 may be present in the first portion, and may not be present in the second portion or the third portion. A third hollow silica particle PT3, which will be described later, may be present in at least one of the first to third portions.

FIG. 7B is a perspective view schematically illustrating a scattering layer according to an example embodiment. Referring to FIGS. 7A and 7B, the first hollow silica particle PT1 may protrude toward the emission layer EML from the upper surface ST_UF of the scattering layer STL. In the hollow silica particles SP, a hollow silica particle located at the upper surface ST_UF of the scattering layer STL and protruding toward the emission layer EML may be defined as the first hollow silica particle PT1. The first hollow silica particle PT1 may partially protrude toward the emission layer EML. A portion of the first hollow silica particle PT1 may be located outside the top surface ST_UF of the scattering layer STL. A portion of the surface of the first hollow silica particle PT1 may be located outside the top surface ST_UF of the scattering layer STL. A portion of the first hollow silica particle PT1 that protrudes toward the emission layer EML may be in contact with a component directly disposed on the scattering layer STL (e.g., the hole transport region HTR or the metal layer AML, see FIG. 7C). A portion of the surface of the first hollow silica particle PT1 may be in contact with a component directly disposed on the scattering layer STL (e.g., the hole transport region HTR or the metal layer AML, see FIG. 7C).

The second hollow silica particle PT2 may have an exposed inner surface caused by partial breakage of the outer surface. In the hollow silica particles SP, a hollow silica particle located at the top surface ST_UF of the scattering layer STL and having an exposed inner surface due to partial breakage of the outer surface may be defined as the second hollow silica particle PT2. A material included in a component directly disposed on the scattering layer STL (e.g., the hole transport region HTR or the metal layer AML, see FIG. 7C) may be present on the exposed inner surface of the second hollow silica particle PT2. In some example embodiments, the exposed inner surface of the second hollow silica particle PT2 may be empty.

The hollow silica particles SP may further include a third hollow silica particle PT3. The third hollow silica particle PT3 may neither protrude toward the emission layer EML nor have an exposed inner surface. In the hollow silica particles SP, a hollow silica particle that does not protrude toward the emission layer EML and does not have an exposed inner surface may be defined as the third hollow silica particle PT3. A plurality of third hollow silica particles PT3 may be provided and may be dispersed in the scattering layer STL. A portion of the third hollow silica particles PT3 may be disposed adjacent to the top surface ST_UF of the scattering layer STL.

A plurality of first and second hollow silica particles PT1 and PT2 may be provided. A plurality of first and second hollow silica particles PT1 and PT2 may be irregularly located on the top surface ST_UF of the scattering layer STL. On the top surface ST_UF of the scattering layer STL, the first and/or second hollow silica particles PT1 and PT2 may exist on one area, and the first and second hollow silica particles PT1 and PT2 may not exist on the other area. The roughness of the area on which the first and/or second hollow silica particles PT1 and PT2 exist may differ from that of the area on which the first and second hollow silica particles PT1 and PT2 do not exist. Accordingly, the top surface ST_UF of the scattering layer STL may have non-uniform roughness. In addition, a third hollow silica particle PT3 disposed adjacent to the top surface ST_UF of the scattering layer STL may be mixed with the first and second hollow silica particles PT1 and PT2 to further enhance the non-uniform roughness of the scattering layer STL. The scattering layer STL including the top surface ST_UF having non-uniform roughness may reduce reflection and diffraction of external light, enhance light extraction efficiency, and/or improve luminance variation according to viewing angles. Luminance variation according to viewing angles refers to a phenomenon in which the luminance changes depending on the position from which the light-emitting surface is viewed. In other words, it may refer to a phenomenon in which the luminance is lower when viewed from a side angle compared to when viewed directly from the front. The first to third hollow silica particles PT1, PT2, and PT3 may reduce (or minimize) reflection and diffraction of external light, enhance light extraction efficiency, and/or improve luminance variation according to viewing angles. Accordingly, the electronic apparatus EA (see FIG. 4) including the scattering layer STL according to an example embodiment may have improved display quality.

A plurality of second hollow silica particles PT2 may be provided. Based on 100% of a total surface area of the top surface ST_UF of the scattering layer STL, a sum of surface areas of the second hollow silica particles PT2 may be in the range of 0.05% to 20%. The surface area refers to a planar surface area. When the sum of the surface areas of the second hollow silica particles PT2 is less than about 0.05% based on 100% of the total surface area of the top surface of the scattering layer, it is not easy to reduce (or minimize) reflection and diffraction of external light. Based on 100% of the total surface area of the top surface of the scattering layer, when the sum of the surface areas of the second hollow silica particles PT2 exceeds about 20%, the light extraction efficiency is not improved, and the durability of the scattering layer is deteriorated. In contrast, in one example embodiment, based on 100% of the total surface area of the top surface ST_UF of the scattering layer STL, a scattering layer STL in which the sum of the surface areas of the second hollow silica particles PT2 is from about 0.05% to about 20% may provide improved durability, may prevent or minimize reflection and diffraction of external light, may improve light extraction efficiency, and/or may improve luminance variation depending on a viewing angle.

Referring again to FIG. 7A, each of the hollow silica particles SP may have a size in the range of about 50 nm to about 200 nm. The size of the hollow silica particle may refer to a length of the hollow silica particle in a cross-sectional (or planar) view. The size may refer to a diameter of the hollow silica particle. When the size of the hollow silica particle is less than about 50 nm, it is not easy to reduce (or minimize) reflection and diffraction of external light. When the size of the hollow silica particle exceeds about 200 nm, the durability of the scattering layer may deteriorate, and thus it may be difficult to provide such particles during formation of the scattering layer, thereby reducing manufacturing efficiency. In contrast, in one example embodiment, the scattering layer STL including the hollow silica particles SP having a size in the range of about 50 nm to about 200 nm may be relatively easy to manufacture and capable of reducing (or minimizing) reflection and diffraction of external light.

Based on 100 wt % of a total weight of the scattering layer STL, a weight of a sum of the hollow silica particles SP may be in the range of about 0.5 wt % to about 15 wt %. The scattering layer STL including the hollow silica particles SP having a total weight in the range of about 0.5 wt % to about 15 wt % based on 100 wt % of the total weight of the scattering layer STL may exhibit improved durability, reduce (or minimize) reflection and diffraction of external light, enhance light extraction efficiency, and/or improve luminance variation according to viewing angles.

A hole transport region HTR may be disposed on the scattering layer STL and the pixel defining film PDL. The hole transport region HTR may be provided as a common layer overlapping a second light-emitting area PXA-G and a light-blocking area NPXA. The hole transport region HTR may include at least one of a hole transport layer, a hole injection layer, or an electron blocking layer. The hole transport region HTR may include a known hole injection material and/or a known hole transport material. For example, the hole transport region HTR may have a thickness in the range of about 50 Å to about 15000 Å.

An emission layer EML may be disposed on the hole transport region HTR. The emission layer EML may be disposed in a region corresponding to the opening PX_OP. In some example embodiments, the emission layer EML may be provided as a common layer. The emission layer EML may include an organic luminescent material, an inorganic luminescent material, an organic-inorganic luminescent material, a quantum dot, or a quantum rod. The emission layer EML may emit light having any one of red, green, or blue colors. For example, the emission layer EML overlapping the second light-emitting area PXA-G may emit green light.

For example, the emission layer EML may have a thickness of about 100 Å to about 1000 Å, or about 100 Å to about 300 Å. The emission layer EML may have a single layer structure including a single material, a single layer structure including materials different from each other, or a multi-layered structure including a plurality of layers with materials different from each other.

An electron transport region ETR may be disposed on the emission layer EML and the pixel defining film PDL. The electron transport region ETR may be provided as a common layer overlapping the second light-emitting area PXA-G and the light-blocking area NPXA. The electron transport region ETR may include at least one of an electron transport layer, an electron injection layer, or a hole blocking layer. The electron transport region ETR may include a known electron injection material and/or a known electron transport material. For example, the electron transport region ETR may have a thickness of about 1000 Å to about 1500 Å.

A second electrode CE may be disposed on the electron transport region ETR and the pixel defining film PDL. The second electrode CE may be provided as a common layer overlapping the second light-emitting area PXA-G and the light-blocking area NPXA.

The second electrode CE may be a common electrode. The second electrode CE may be a cathode or an anode, but example embodiments are not limited thereto. For example, when the first electrode AE is the anode, the second electrode CE may be the cathode, and when the first electrode AE is the cathode, the second electrode CE may be the anode.

The second electrode CE may be a transmissive electrode, a transflective electrode, or a reflective electrode. When the second electrode CE is the transmissive electrode, the second electrode CE may be made of or include metal oxide, for example, indium tin oxide (ITO), indium zinc oxide (IZO), zinc oxide (ZnO), or indium tin zinc oxide (ITZO).

When the second electrode CE is the transflective electrode or the transmissive electrode, the second electrode CE may include g, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, or MgYb) In some example embodiments, the second electrode CE may have a multi-layered structure including a reflective layer or transflective layer and a transparent conductive layer made of or including indium tin oxide (ITO), indium zinc oxide (IZO), zinc oxide (ZnO), or indium tin zinc oxide (ITZO). For example, the second electrode CE may include the above-described metal materials, a combination of two or more metal materials of the above-described metal materials, or oxide of the above-described metal materials.

The encapsulation layer TFE may be disposed on the display element layer DP-EL. The encapsulation layer TFE may be disposed on the second electrode CE to cover the light-emitting element ED. The encapsulation layer TFE may protect the display element layer DP-EL against foreign substances such as moisture, oxygen, and/or dust particles. The encapsulation layer TFE may include a plurality of thin films.

The encapsulation layer TFE may include at least one inorganic film. For example, the encapsulation layer TFE may include inorganic films disposed on the second electrode CE and an organic film disposed between the inorganic films. The inorganic film may protect the light-emitting element ED from moisture/oxygen, and the organic film may protect the light-emitting element ED from foreign substances such as dust particles.

An input sensing layer TP may be disposed on the display panel DP. For example, the input sensing layer TP may be directly disposed on the encapsulation layer TFE of the display panel DP. In some example embodiment, an adhesive layer may be disposed between the input sensing layer TP and the display panel DP.

The input sensing layer TP may include a first sensing insulating layer IL1, a second sensing insulating layer IL2, and a third sensing insulating layer IL3. The input sensing layer TP may include at least one conductive layer disposed on the sensing insulating layers IL1 and IL2. The input sensing layer TP may include a first conductive layer CDL1 and a second conductive layer CDL2.

The first sensing insulating layer IL1 may be disposed on the encapsulation layer TFE. The first sensing insulating layer IL1 may include at least one inorganic insulating layer. The first sensing insulating layer IL1 may be in contact with the encapsulation layer TFE. In contrast, the first sensing insulating layer IL1 may be omitted, in which case the first conductive layer CDL1 may be in contact with the encapsulation layer TFE.

The first conductive layer CDL1 may be disposed on the first sensing insulating layer IL1. The first conductive layer CDL1 may include a plurality of first conductive patterns. The plurality of first conductive patterns may be disposed on the first sensing insulating layer IL1. The second sensing insulating layer IL2 may be disposed on the first sensing insulating layer IL1 to cover at least a portion of the first conductive layer CDL1.

The second conductive layer CDL2 may be disposed on the second sensing insulating layer IL2. The second conductive layer CDL2 may include a plurality of second conductive patterns. The plurality of second conductive patterns may be disposed on the second sensing insulating layer IL2. Each of the plurality of second conductive patterns may be connected to the plurality of first conductive patterns through a contact hole defined in the second sensing insulating layer IL2.

Each of a plurality of first conductive patterns of the first conductive layer CDL1 and a plurality of second conductive patterns of the second conductive layer CDL2 may be disposed corresponding to the light-blocking area NPXA. Each of the plurality of first conductive patterns of the first conductive layer CDL1 and the plurality of second conductive patterns of the second conductive layer CDL2 may be a mesh pattern.

The third sensing insulating layer IL3 may be disposed on the second sensing insulating layer IL2 and may cover the second conductive layer CDL2. Each of the second sensing insulating layer IL2 and the third sensing insulating layer IL3 may include an inorganic insulating layer or an organic insulating layer.

Each of the first conductive layer CDL1 and the second conductive layer CDL2 may have a single-layer structure, or may have a multilayer structure stacked along a third direction DR3. The conductive layers CDL1 and CDL2, each of which has the single-layer structure, may include a conductive metal layer or a transparent conductive layer. The conductive metal layer may include molybdenum, silver, titanium, copper, aluminum, or alloys thereof. The transparent conductive layer may include a transparent conductive oxide such as indium tin oxide (ITO), indium zinc oxide (IZO), zinc oxide (ZnO), or indium tin zinc oxide (ITZO). In addition, the transparent conductive layer may include a conductive polymer such as poly(3,4-ethylenedioxythiophene (PEDOT), a metal nanowire, graphene, etc.

The multilayer conductive layers CDL1 and CDL2 may include conductive metal layers. The conductive metal layers may have, for example, a three-layer structure of titanium (Ti)/aluminum (Al)/titanium (Ti). The multilayer conductive layers CDL1 and CDL2 may include at least one conductive metal layer and at least one transparent conductive layer.

The optical layer PP may be disposed on the input sensing layer TP. The optical layer PP may include a pattern portion BM and a color filter CF. The pattern portion BM may be defined with a sub-opening B_OP. The color filter CF may be disposed to fill the sub-opening B_OP. In addition, the optical layer PP may further include an overcoat layer OC disposed on the pattern portion BM and the color filter CF.

The pattern portion BM may overlap the light-blocking area NPXA and may not overlap the second light-emitting area PXA-G. The material constituting the pattern portion BM may be used without limitation as long as it is a light-absorbing material. The pattern portion BM may have a black color, and may include a black coloring agent. The block coloring agent may include a black dye and/or a black pigment. The black coloring agent may include carbon black, metal such as chromium, or oxides thereof.

The color filter CF may be disposed corresponding to the emission layer EML. The color filter CF may include a pigment or a dye. For example, the color filter CF corresponding to the emission layer EML that emits green light may include a green pigment or a green dye. The color filter CF corresponding to the emission layer EML that emits green light may be a green filter. The optical layer PP including the color filter CF containing a pigment or dye may improve display quality of the display device DD. An electronic apparatus EA including the display device DD (see FIG. 4) may provide improved display quality.

The overcoat layer OC may cover the pattern portion BM and the color filter CF. The overcoat layer OC may include an organic material. The overcoat layer OC may be a planarization layer.

FIG. 7C is a cross-sectional view showing a display device according to another example embodiment of the inventive concepts. In the following description of FIG. 7C, overlapping content with the descriptions referring to FIGS. 1 to 7B will not be repeated, and the differences will mainly be described.

Compared to the display device DD shown in FIG. 7A, a display device DD-a shown in FIG. 7C differs in that a light-emitting element ED-a further includes a metal layer AML. The light-emitting element ED-a may further include the metal layer AML disposed between the scattering layer STL and the emission layer EML. More specifically, the metal layer AML may be disposed between the scattering layer STL and a hole transport region HTR.

The metal layer AML may be directly disposed on the scattering layer STL. The metal layer AML may be disposed within an opening PX_OP of the pixel defining film PDL. The metal layer AML may be in contact with an inner surface of the pixel defining film PDL defining the opening PX_OP of the pixel defining film PDL. The scattering layer STL may be directly disposed between the metal layer AML and the first electrode AE. The metal layer AML may not be in contact with the first electrode AE.

The metal layer AML may include at least one selected from (e.g., at least one of) Ag, Mg, Cu, Al, Pt, Pd, Au, Ni, Nd, Ir, Cr, Li, Ca, LiF, Mo, Ti, W, In, Sn, or Zn, a compound of two or more selected therefrom, a mixture of two or more selected therefrom, or an oxide of a ny one thereof. The metal layer AML may improve driving characteristics of the light-emitting element ED-a.

The metal layer AML may include the same material as the first electrode AE. For example, the metal layer AML may include a transparent conductive film formed of or including ITO (indium tin oxide), IZO (indium zinc oxide), ZnO (zinc oxide), or ITZO (indium tin zinc oxide). For example, the first electrode AE may have a three-layer structure of ITO/Ag/ITO, and the metal layer AML may include ITO.

In the thickness direction DR3, the metal layer AML may have a thickness of about 200 Å to about 500 Å. The metal layer AML having a thickness of about 200 Å to about 500 Å may improve driving characteristics of the light-emitting element ED-a without increasing the driving voltage or decreasing the light extraction efficiency.

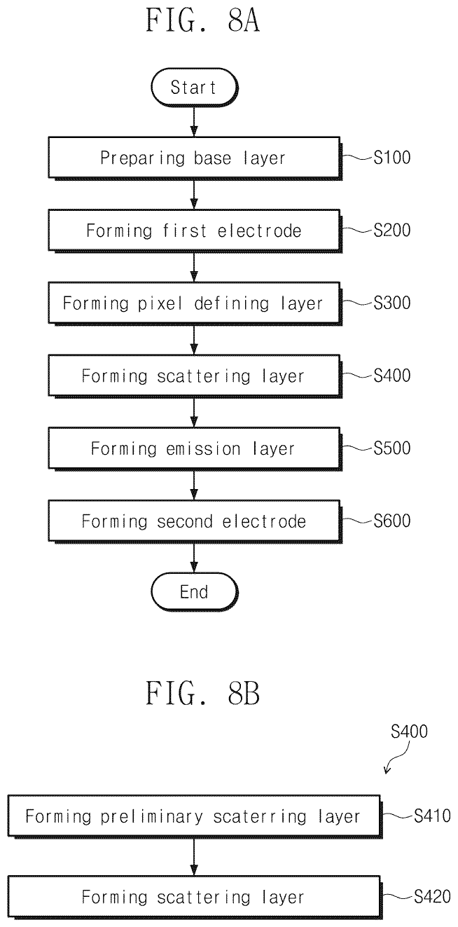

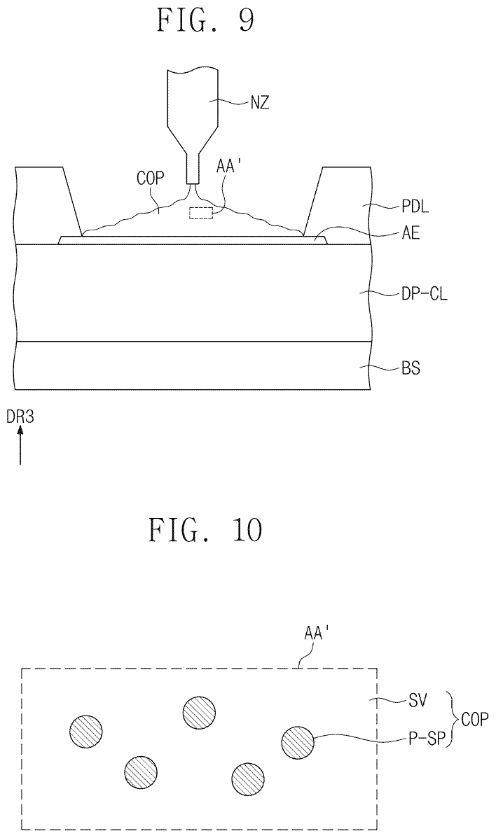

An electronic apparatus according to one example embodiment may be manufactured by a method for manufacturing an electronic apparatus according to one example embodiment. FIGS. 8A and 8B are flowcharts illustrating a method for manufacturing an electronic apparatus according to one example embodiment. FIGS. 9 to 12 are schematic views illustrating operations of manufacturing the electronic apparatus according to one example embodiment. In the following description of FIGS. 8A to 12, overlapping contents with those described with reference to FIGS. 1 to 7C will not be repeated, and differences will mainly be described.

Referring to FIG. 8A, the method for manufacturing the electronic apparatus according to one example embodiment may include an operation S100 of preparing a base layer, an operation S200 of forming a first electrode on the base layer, an operation S300 of forming a pixel defining film defining an opening exposing the first electrode, an operation S400 of forming a scattering layer on the first electrode, an operation S500 of forming an emission layer on the scattering layer, and an operation S600 of forming a second electrode on the emission layer. Referring to FIG. 8B, the step S400 of the forming the scattering layer may include an operation S410 of forming a preliminary scattering layer, and an operation S420 of treating the preliminary scattering layer with plasma to form the scattering layer.

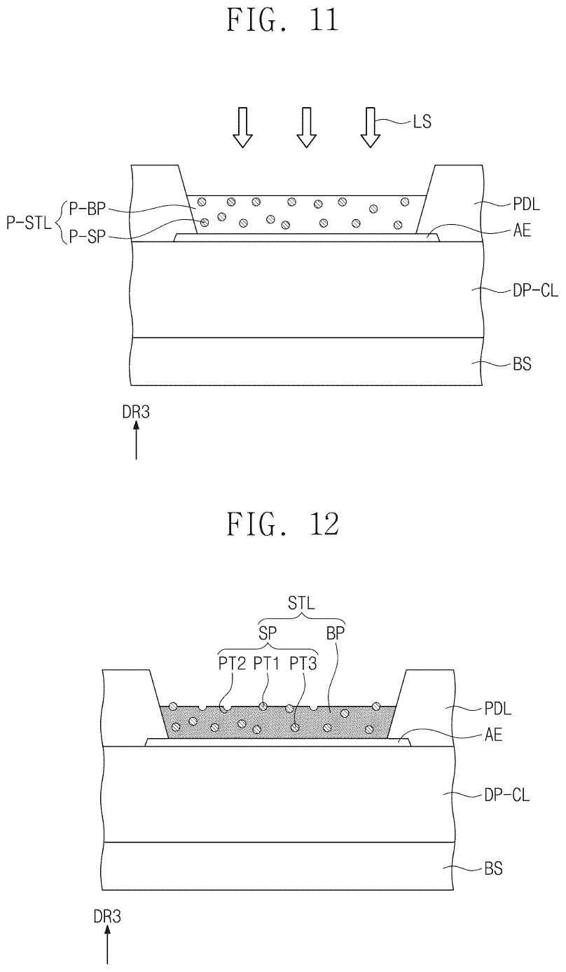

Referring to FIG. 9, a composition COP for forming a preliminary scattering layer P-STL (see FIG. 11) may be provided on the first electrode AE. The preliminary scattering layer P-STL may be formed by an inkjet printing method, a dispensing method, or a photolithography method. The composition COP may be provided by an inkjet printing method, a dispensing method, or a photolithography method. In FIG. 9, the composition COP is illustrated as being provided through a nozzle NZ, but the providing apparatus for the composition COP is not limited thereto.

FIG. 10 is an enlarged view of region AA′ in FIG. 9. Referring to FIG. 10, the composition COP may include an organic solvent SV and a plurality of preliminary hollow silica particles P-SP dispersed in the organic solvent SV. The preliminary hollow silica particles P-SP may be substantially identical to the third hollow silica particles PT3 (see FIG. 7A) described above. A preliminary base portion P-BP (see FIG. 11) may be formed from the organic solvent SV, and a base portion BP (see FIG. 12) may be formed from the preliminary base portion P-BP. For example, the organic solvent SV may include an acryl-based resin.

Based on 100 wt % of the total weight of the composition COP, the weight of the preliminary hollow silica particles P-SP may be in the range of about 0.5 wt % to about 15 wt %. Each preliminary hollow silica particle P-SP may have a size of about 50 nm to about 200 nm. The hollow silica particles P-SP having a size of about 50 nm to about 200 nm may be easily provided by an inkjet printing method or a photolithography method.

The preliminary scattering layer P-STL shown in FIG. 11 may be formed by curing the composition COP provided on the first electrode AE. For example, heat or light may be provided when curing the composition COP. The preliminary scattering layer P-STL may include the preliminary base portion P-BP and the preliminary hollow silica particles P-SP. The preliminary scattering layer P-STL may be treated with plasma LS, and the scattering layer STL (see FIG. 12) may be formed. In the operation of the forming of the scattering layer STL, fluorine plasma or oxygen plasma may be provided. When performing the treatment of the plasma LS, fluorine gas or oxygen gas may be provided as plasma. For example, CF4 or NF3 may be provided as the fluorine gas.

Referring to FIGS. 11 and 12, by treating the preliminary scattering layer P-STL with plasma LS, the base portion BP (see FIG. 12) may be formed from the preliminary base portion P-BP, and hollow silica particles SP may be formed from the preliminary hollow silica particles P-SP. The first and second hollow silica particles PT1 and PT2 may be formed by the plasma LS treatment. In the operation of the treating with plasma LS, the preliminary base portion P-BP may be etched. The first and second hollow silica particles PT1 and PT2 may be formed simultaneously with the etching of the preliminary base portion P-BP. When the preliminary base portion P-BP is etched, some of the preliminary hollow silica particles P-SP may protrude to form the first hollow silica particles PT1. In addition, in the operation of treating with plasma LS, some of the preliminary hollow silica particles P-SP may have broken surfaces, and second hollow silica particles PT2 with exposed inner surfaces may be formed. The bond between silicon atoms and oxygen atoms constituting the hollow silica particles may be broken by the fluorine gas (or oxygen gas), and second hollow silica particles PT2 with exposed inner surfaces may be formed. Accordingly, the method for manufacturing an electronic apparatus according to one example embodiment, including the operation of treating with plasma LS, may provide improved processability.

Referring to FIG. 13, the method for manufacturing the electronic apparatus according to one example embodiment may further include an operation of forming a metal layer AML between the operation of forming the scattering layer STL and the operation of forming the emission layer EML (see FIG. 7c). The metal layer AML may include at least one selected from (e.g., at least one of) Ag, Mg, Cu, Al, Pt, Pd, Au, Ni, Nd, Ir, Cr, Li, Ca, LiF, Mo, Ti, W, In, Sn, or Zn, a compound of two or more selected therefrom, a mixture of two or more selected therefrom, or an oxide of any one thereof. Before forming the emission layer EML (see FIG. 7c), an ashing process may be performed on the metal layer AML. Through the ashing process, the work function of the metal layer AML may be corrected, and the driving characteristics of the light-emitting element ED-a may be improved. For example, oxygen gas AH may be provided in the ashing process. When the oxygen gas AH is provided, the oxygen content of the surface of the metal layer AML may increase. A relatively high content of oxygen may be present on the surface of the metal layer AML.

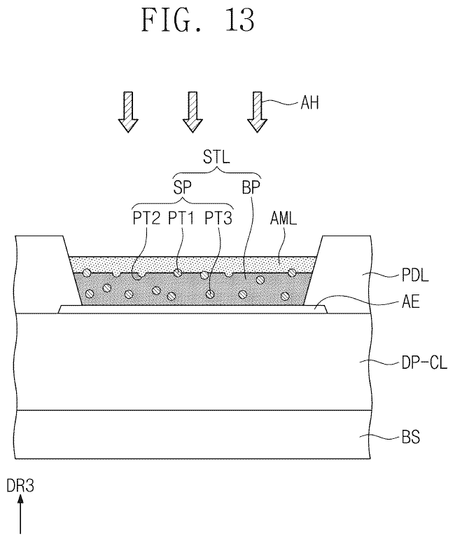

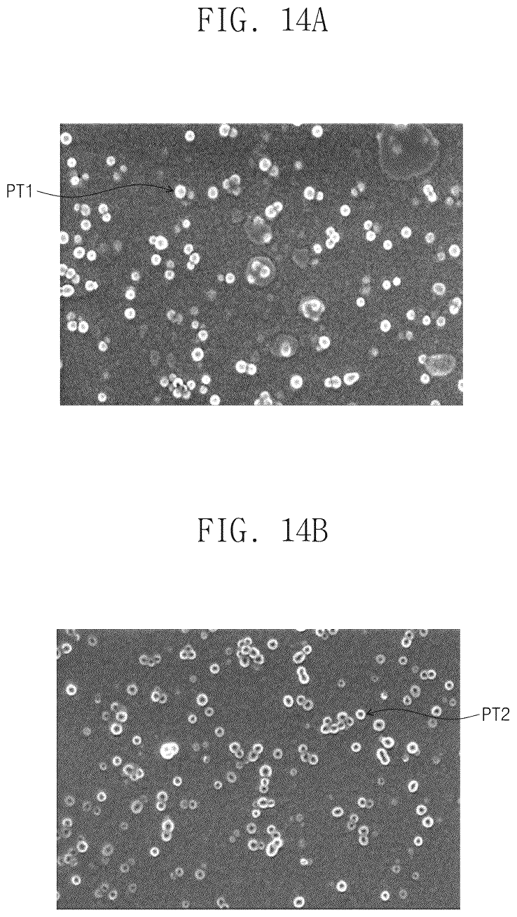

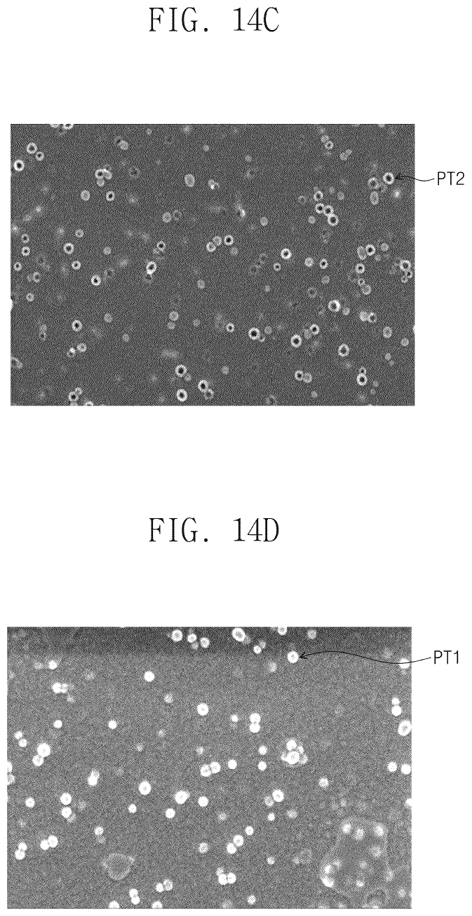

FIGS. 14A to 14D are images of the pixel defining film of the experimental example after plasma treatment, and the images were captured using a scanning electron microscope (SEM). In FIGS. 14A to 14D, the pixel defining film of the experimental example includes hollow silica particles.

CF4 was provided during the plasma treatment in the experimental examples of FIGS. 14A and 14B. NF3 was provided during the plasma treatment in the experimental examples of FIGS. 14C and 14d. Plasma treatment was performed for 120 seconds with a source voltage of 0.5 kW and a bias voltage of 0 kW in the experimental examples of FIGS. 14A and 14C. Plasma treatment was performed for 120 seconds with a source voltage of 0.5 kW and a bias voltage of 0 kW in the experimental examples of FIGS. 14A and 14C.

Referring to FIGS. 14A and 14D, the first hollow silica particles PT1 protruded by the plasma treatment may be identified. Referring to FIGS. 14B and 14C, the second hollow silica particles PT2 with exposed inner surfaces due to the plasma treatment may be identified. Accordingly, it may be understood that when plasma is applied to the preliminary scattering layer including preliminary hollow silica particles, the protruded first hollow silica particles and the second hollow silica particles with exposed inner surfaces may be formed.

When analyzing the images of FIGS. 14B and 14C using the Image J analysis program (which is an open-source image analysis program developed by the National Institutes of Health (NIH)), only the second hollow silica particles with exposed inner surfaces may be independently recognized. The recognition area is darkened so that the surface area of the second hollow silica particles may be converted into a fractional percentage.

The method for manufacturing an electronic apparatus according to one example embodiment may include an operation of treating a preliminary scattering layer with plasma to form a scattering layer. The first and second hollow silica particles may be formed through the plasma treatment. Accordingly, the method for manufacturing an electronic apparatus according to one example embodiment may provide improved processability.

An electronic apparatus according to one example embodiment may be manufactured by the method for manufacturing an electronic apparatus. The electronic apparatus according to one example embodiment may include a scattering layer disposed on the first electrode and including the first and second hollow silica particles. The first and second hollow silica particles may be located on the top surface of the scattering layer. The first hollow silica particles may be protruded toward the emission layer direction from the top surface of the scattering layer. The second hollow silica particles may have broken surfaces with exposed interiors. The scattering layer including the first and second hollow silica particles may improve reflection and/or diffraction of external light, enhance light extraction efficiency, and/or improve luminance variation depending on the viewing angle. The electronic apparatus including the scattering layer may have improved display quality.

Because the electronic apparatus according to one example embodiment includes the first and second hollow silica particles, it may have improved display quality.

The method for manufacturing the electronic apparatus according to one example embodiment may include an operation of forming the first and second hollow silica particles through plasma treatment, thereby providing improved processability.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although some example embodiments of the inventive concepts have been described, it is understood that the inventive concepts should not be limited to these example embodiments but various changes and modifications can be made by one ordinary skilled in the art within the spirit and scope of the inventive concepts as hereinafter claimed.

What is claimed is:

1. An electronic apparatus comprising:
a display module comprising a light-emitting element and a pixel defining film including an opening,
wherein the light-emitting element comprises
a first electrode exposed through the opening,
a scattering layer on the first electrode,
an emission layer on the scattering layer, and
a second electrode on the emission layer,
wherein the scattering layer comprises
a base portion, and
a plurality of hollow silica particles dispersed in the base portion, the plurality of hollow silica particles comprising a first hollow silica particle and a second hollow silica particle,
wherein the first hollow silica particle is on a top surface of the scattering layer and protrudes from the top surface toward the emission layer, the top surface of the scattering layer being spaced apart from the first electrode, and
wherein the second hollow silica particle is on the top surface of the scattering layer and has an exposed inner surface.

2. The electronic apparatus of claim 1, wherein the second hollow silica particle includes a plurality of second hollow silica particles, and based on 100% of a total surface area of the top surface of the scattering layer, a sum of surface areas of the plurality of second hollow silica particles is about 0.05% or more and about 20% or less.

3. The electronic apparatus of claim 1, wherein each of the plurality of hollow silica particles has a size of about 50 nm to about 200 nm.

4. The electronic apparatus of claim 1, wherein, based on a total weight of the scattering layer, a total weight of the plurality of hollow silica particles is about 0.5 wt % or more and about 15 wt % or less.

5. The electronic apparatus of claim 1, wherein the scattering layer is in the opening of the pixel defining film.

6. The electronic apparatus of claim 1, wherein
the light-emitting element further comprises a metal layer between the scattering layer and the emission layer,
wherein the metal layer comprises at least one selected from of Ag, Mg, Cu, Al, Pt, Pd, Au, Ni, Nd, Ir, Cr, Li, Ca, LiF, Mo, Ti, W, In, Sn, or Zn, compounds of two or more selected from Ag, Mg, Cu, Al, Pt, Pd, Au, Ni, Nd, Ir, Cr, Li, Ca, LiF, Mo, Ti, W, In, Sn, or Zn; mixtures of two or more selected from Ag, Mg, Cu, Al, Pt, Pd, Au, Ni, Nd, Ir, Cr, Li, Ca, LiF, Mo, Ti, W, In, Sn, or Zn; or oxides of Ag, Mg, Cu, Al, Pt, Pd, Au, Ni, Nd, Ir, Cr, Li, Ca, LiF, Mo, Ti, W, In, Sn, or Zn.

7. The electronic apparatus of claim 6, wherein the metal layer is directly on the scattering layer.

8. The electronic apparatus of claim 6, wherein the metal layer has a thickness of about 200 Å to about 500 Å.

9. The electronic apparatus of claim 6, wherein the metal layer is in the opening of the pixel defining film.

10. The electronic apparatus of claim 1, wherein the plurality of hollow silica particles further comprise a third hollow silica particle that do not protrude from the top surface of the scattering layer toward the emission layer and do not have exposed inner surfaces.

11. The electronic apparatus of claim 1, wherein the base portion comprises an organic material.

12. The electronic apparatus of claim 1, further comprising:
at least one of a processor, power supply circuitry, or a memory.

13. A method for manufacturing an electronic apparatus, comprising:
preparing a base layer;
forming a first electrode on the base layer;
forming a pixel defining film having an opening through which the first electrode is exposed;
forming a scattering layer on the first electrode;
forming an emission layer on the scattering layer; and
forming a second electrode on the emission layer,
wherein the forming of the scattering layer comprises
forming a preliminary scattering layer on the first electrode, the preliminary scattering layer including a preliminary base portion and a plurality of preliminary hollow silica particles dispersed in the preliminary base portion, and
treating the preliminary scattering layer with plasma to form the scattering layer comprising a base portion and a plurality of hollow silica particles that are formed from the preliminary base portion and the plurality of preliminary hollow silica particles, respectively,
wherein the plurality of hollow silica particles comprise a first hollow silica particle and a second hollow silica particle,
wherein the first hollow silica particle is disposed on a top surface of the scattering layer and protrudes toward the emission layer from the top surface of the scattering layer, the top surface of the scattering layer being spaced apart from the first electrode, and
the second hollow silica particle is disposed on the top surface of the scattering layer and have an exposed inner surface.

14. The method for claim 13, wherein the plasma comprises fluorine plasma or oxygen plasma.

15. The method for claim 13, wherein the preliminary base portion is etched in the treating of the plasma.

16. The method for claim 13, wherein a total weight of the plurality of hollow silica particles is about 0.5 wt % or more and about 15 wt % or less based on a total weight of the scattering layer.

17. The method for claim 13, wherein each of the plurality of hollow silica particles has a size of about 50 nm to about 200 nm.

18. The method for claim 13, wherein the preliminary scattering layer is formed by an inkjet printing method or a photolithography method.

19. The method for claim 13, further comprising:
forming a metal layer on the scattering layer between the forming of the scattering layer and the forming of the emission layer,
wherein the metal layer comprises at least one selected from Ag, Mg, Cu, Al, Pt, Pd, Au, Ni, Nd, Ir, Cr, Li, Ca, LiF, Mo, Ti, W, In, Sn, or Zn; a compound of two or more selected from Ag, Mg, Cu, Al, Pt, Pd, Au, Ni, Nd, Ir, Cr, Li, Ca, LiF, Mo, Ti, W, In, Sn, or Zn; a mixture of two or more selected from Ag, Mg, Cu, Al, Pt, Pd, Au, Ni, Nd, Ir, Cr, Li, Ca, LiF, Mo, Ti, W, In, Sn, or Zn; or oxides of any one of Ag, Mg, Cu, Al, Pt, Pd, Au, Ni, Nd, Ir, Cr, Li, Ca, LiF, Mo, Ti, W, In, Sn, and Zn.

20. The method for claim 19, further comprising:
performing an ashing process on the metal layer before the forming of the emission layer.
